(19) United States
(12) Patent Application Publication
(10) Pub. No.: US 2008/0206023 A1
(43) Pub. Date: Aug. 28, 2008

(54) Semiconductor substrate processing apparatus with horizontally clustered vertical stacks

(76) Inventors: John M. Smith, Austin, TX (US); James Carter Hall, Georgetown, TX (US); Jeffrey G. Ellison, Austin, TX (US)

Correspondence Address: MEYERTONS, HOOD, KIVLIN, KOWERT & GOETZEL, P.C., P.O. BOX 398, AUSTIN, TX, 78767-0398, US

(21) Appl. No.: 11/711,476

(22) Filed: Feb. 27, 2007

(51) Int. Cl. H01L 21/677

(52) U.S. Cl. 414/217.1; 901/2

(57) ABSTRACT

A substrate processing apparatus is described. The apparatus includes a substrate load lock chamber. A plurality of storage bays may be used to store semiconductor substrates. A first set of one or more multi-axis robot arms may transfer one or more semiconductor substrates between the substrate load lock chamber and the plurality of storage bays. A substrate transfer chamber is vacuum coupled to the substrate load lock chamber. A plurality of process chamber modules are vacuum coupled to the substrate transfer chamber. A second set of one or more multi-axis robot arms may transfer semiconductor substrates between the storage bays and the plurality of process chamber modules under sub-atmospheric conditions.

### PRIORITY CLAIM

This patent application claims priority to U.S. Provisional Patent No. 60/772,102 entitled “SEMICONDUCTOR SUBSTRATE PROCESSING APPARATUS WITH HORIZONTALLY CLUSTERED VERTICAL STACKS” to Smith et al. filed on Feb. 27, 2006.

### BACKGROUND

1. Field of the Invention

The present invention relates generally to substrate processing apparatus. Certain embodiments relate to configurations and designs for a substrate processing apparatus.

2. Description of Related Art

Substrate (e.g., semiconductor wafer) processing technology continues to progress towards processing of larger substrate sizes. As technology shifts from smaller substrate sizes to larger substrate sizes, substrate processing equipment for smaller substrate sizes becomes obsolete. Substrate processing equipment is typically designed to operate at one substrate size. Upgrading a substrate (e.g., a semiconductor wafer) fabrication facility to process a larger substrate size currently involves replacing all or a majority of the substrate processing equipment in the fabrication facility. The replacement of equipment is a large capital expense that many facilities cannot or do not wish to afford.

A factor in fabrication facilities as substrate sizes increase is the limited amount of cleanroom space available in these facilities. Larger process chambers are required to process the larger substrate sizes. Thus, as substrate size increases so does the equipment used to process the substrates. Cleanroom space is relatively expensive so it can become costly to enlarge current cleanrooms and/or obtain new larger cleanroom facilities.

Current sub-atmospheric cluster tools typically have a substrate transfer chamber surrounded by several processing chambers in a horizontally clustered configuration. As substrate sizes increase, the size of the process chambers increases and the number of process chambers that can be clustered around the substrate transfer chamber decreases. Additionally, larger substrates (e.g., 450 mm or greater) may only be processed one substrate at a time in the process chamber. Thus, as substrate sizes increase, throughput for processing the substrates decrease.

### SUMMARY

In certain embodiments, a substrate (e.g., a semiconductor substrate or semiconductor wafer) processing apparatus is able to process substrates with a selected diameter in a range from about 100 mm to about 450 mm. The apparatus may be able to bridge (e.g., be backward and forward compatible) with several different sizes of substrate diameters. The apparatus may be physically adjusted or adapted to configure the apparatus to process substrates with a selected diameter.

In certain embodiments, the substrate processing apparatus includes a substrate load lock chamber. A substrate transfer chamber may be vacuum coupled to the substrate load lock chamber. A plurality of process chambers may be vacuum coupled to the substrate transfer chamber. At least two of the process chambers are horizontally clustered around the substrate transfer chamber. At least two of the process chambers are vertically arranged with one process chamber above the other process chamber.

In certain embodiments, the substrate transfer chamber includes one or more robotic arms for transferring substrates between the load lock chamber and the plurality of process chambers. In some embodiments, the robotic arms are multi-axis robotic arms. In certain embodiments, each of the process chambers is coupled to its own dedicated support system so that each process chamber along with its dedicated support system can be disconnected from the substrate transfer chamber without disrupting any of the other process chambers.

In some embodiments, an operating system automatically controls the processing of a plurality of substrates in the apparatus. The operating system may automatically control at least: a) the transfer of substrates between the load lock and the process chambers; (b) the transfer of substrates between process chambers; and (c) the operation of the process chambers.

### BRIEF DESCRIPTION OF THE DRAWINGS

Advantages of the present invention may become apparent to those skilled in the art with the benefit of the following detailed description and upon reference to the accompanying drawings in which:

FIG. 1 depicts a representation of an embodiment of a substrate processing apparatus.

FIG. 1A depicts a top view schematic representation of an embodiment of a substrate processing apparatus.

FIG. 2 depicts a side view schematic representation of an embodiment of the substrate processing apparatus depicted in FIG. 1.

FIG. 3 depicts a representation of an embodiment of a substrate loading chamber.

FIG. 4 depicts a representation of an embodiment of a robot arm and a robotic controller on a rail.

FIG. 5 depicts an end view representation of an embodiment of a substrate transfer chamber with storage bays.

FIG. 6 depicts a top view schematic representation of an embodiment of a substrate transfer chamber showing storage bays.

FIG. 7 depicts a representation of an embodiment of a load lock chamber with multiple openings.

FIG. 8 depicts a representation of an embodiment of a slit gate valve.

FIG. 9 depicts a representation of an embodiment of a process chamber module.

FIG. 10 depicts an example of a variable size substrate holder in a process chamber.

FIG. 11 depicts a side view representation of an embodiment of a vacuum curtain located between a load lock chamber and a substrate transfer chamber.

FIG. 12 depicts a front view representation of an embodiment of a vacuum curtain.

FIG. 13 depicts a side view representation of the embodiment of the vacuum curtain depicted in FIG. 12.

While the invention is susceptible to various modifications and alternative forms, specific embodiments thereof are shown by way of example in the drawings and may herein be described in detail. The drawings may not be to scale. It should be understood, however, that the drawings and detailed description thereto are not intended to limit the invention to the particular form disclosed, but on the contrary, the intention is to cover all modifications, equivalents, and alternatives falling within the spirit and scope of the present invention as defined by the appended claims.

### DETAILED DESCRIPTION

In the context of this patent, the term “coupled” means either a direct connection or an indirect connection (e.g., one or more intervening connections) between one or more objects or components. The phrase “directly connected” means a direct connection between objects or components such that the objects or components are connected directly to each other so that the objects or components operate in a “point of use” manner.

The phrase “vacuum coupled” means that two or more components are coupled so that the components are vacuum sealed to each other and the components may together maintain a common sub-atmospheric pressure (e.g., a sub-atmospheric condition). Vacuum coupled components may be “vacuum isolated” from each other so that the vacuum isolated components have differing pressure conditions (e.g., one chamber is at atmospheric conditions and one chamber is at sub-atmospheric conditions). The components may be vacuum isolated from each other using valves (e.g., vacuum valves or gate valves).

“Substrate” in this application refers to a body or base layer on which one or more processes are performed. For example, layers or films may be deposited onto a substrate in one or more processes. The processes may also include etching and/or patterning the substrate and/or layers deposited onto the substrate. Examples of substrates that may be used in this application include, but are not limited to, semiconductor substrates (e.g., semiconductor wafers), flat-panel display substrates (e.g., substrates for plasma or LCD displays), magnetic media substrates (e.g., substrates for hard drives or flyheads), and nanotubes.

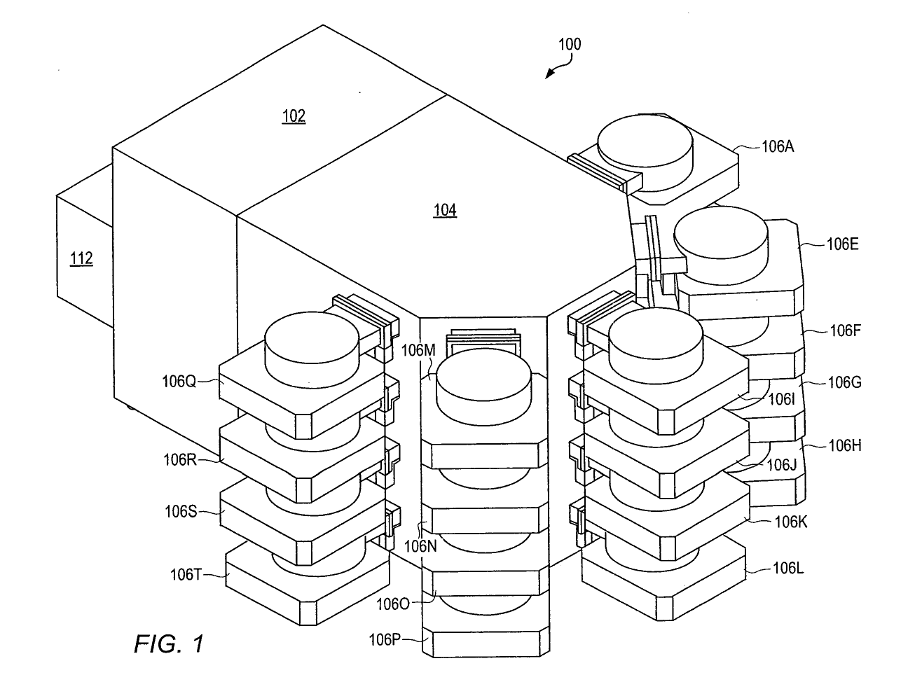

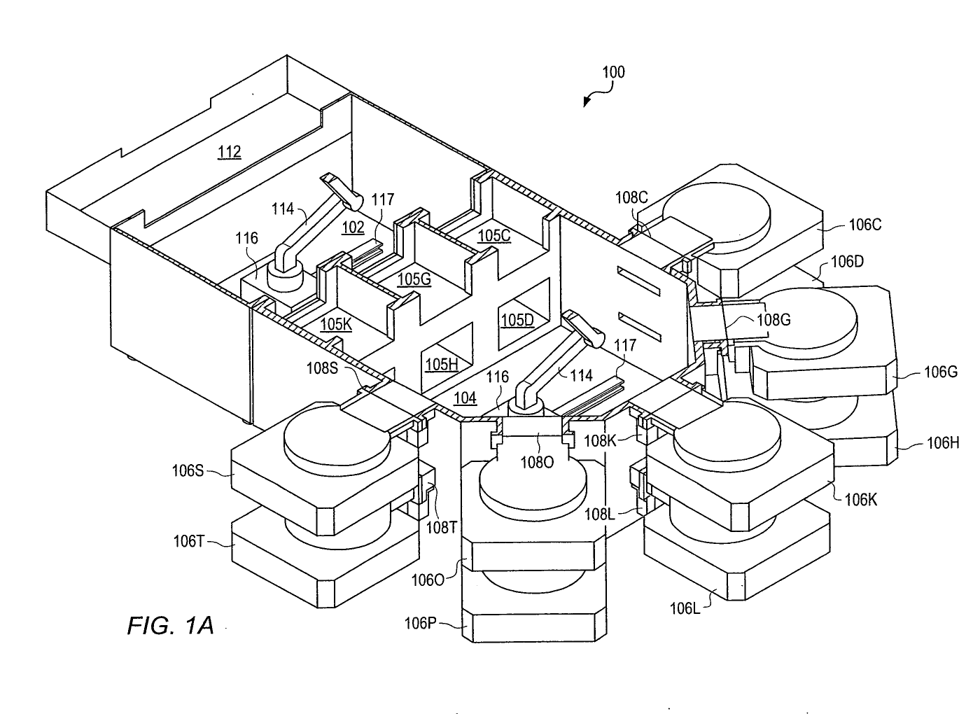

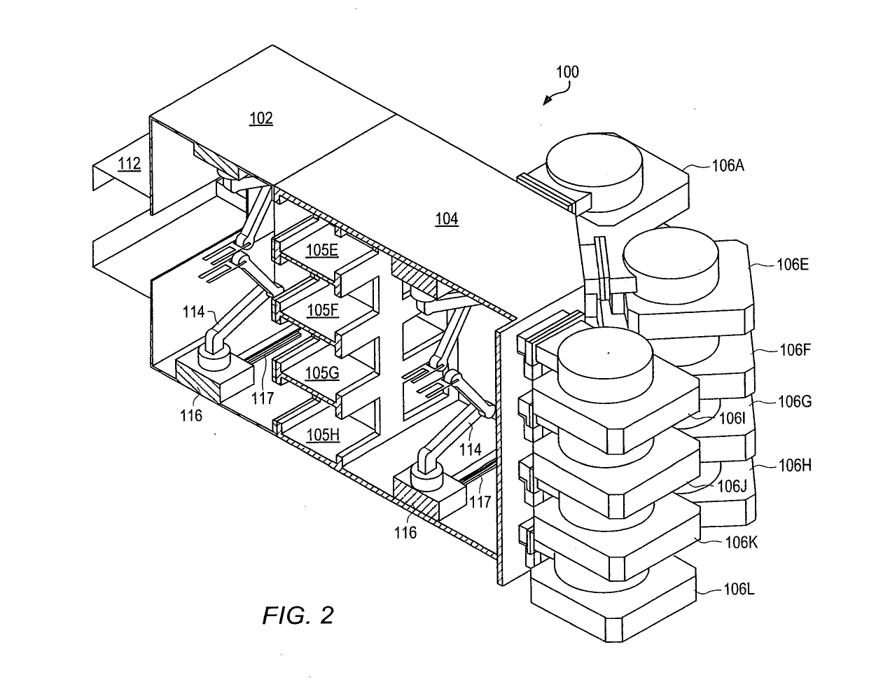

FIG. 1 depicts a representation of an embodiment of an embodiment of substrate processing apparatus 100. FIG. 1A depicts a top view schematic representation of the embodiment of substrate processing apparatus 100 depicted in FIG. 1. FIG. 2 depicts a side view schematic representation of the embodiment of substrate processing apparatus 100 depicted in FIGS. 1 and 1A. Apparatus 100 is used to process substrates and produce one or more devices on the substrates under sub-atmospheric conditions (e.g., high vacuum (HV) or ultra high vacuum (UHV) conditions). Apparatus 100 includes substrate loading chamber 112, load lock chamber 102, substrate transfer chamber 104, and process chamber modules 106A-L. Substrate loading chamber 112, load lock chamber 102, substrate transfer chamber 104, and process chamber modules 106A-L may operate under sub-atmospheric conditions. Apparatus 100 may be located in a substrate (e.g., a semiconductor or cleanroom) processing facility. In certain embodiments, apparatus 100 is located in one room (e.g., a utility chase) and coupled to a cleanroom. In certain embodiments, the front end of substrate loading chamber 112 interfaces with the cleanroom so that substrates may be loaded into the load lock chamber from the cleanroom. In some embodiments, apparatus 100 is located in the cleanroom.

In certain embodiments, substrate loading chamber 112 is coupled to load lock chamber 102 for the loading and unloading of substrates from the load lock chamber. A representation of an embodiment of substrate loading chamber 112 is depicted in FIG. 3. As shown in FIGS. 1A and 2, substrate loading chamber 112 may be vacuum coupled to load lock chamber 102. Substrate loading chamber 112 includes one or more load lock doors that interface with, for example, a cleanroom or other substrate handling facility. Substrates and/or substrate carriers may be automatically (e.g., robotically) or manually provided into substrate loading chamber 112 from the cleanroom. Substrate carriers may be, for example, substrate cassettes that hold a plurality of substrates (e.g., semiconductor substrates).

Substrates and/or substrate carriers may enter load lock chamber 102 through substrate loading chamber 112. While a load lock door is open, substrate loading chamber 112 may be vacuum isolated from load lock chamber 102 by closing one or more valves between the substrate loading chamber and the load lock chamber so that sub-atmospheric conditions are maintained in the load lock chamber while the substrate loading chamber is at atmospheric conditions. When the load lock doors are closed, substrate loading chamber 112 is vacuum pumped to sub-atmospheric conditions so that substrates and/or substrate carriers may be transferred between the substrate loading chamber and load lock chamber 102 under sub-atmospheric conditions. Substrates and/or substrate carriers may be transferred between substrate loading chamber 112 and load lock chamber 102 using automation (e.g., robot arms 114 or other conveyor systems known in the art).

In certain embodiments, load lock chamber 102 includes one or more robot arms 114 for transferring substrates between substrate loading chamber 112, load lock chamber 102, and substrate transfer chamber 104. In an embodiment, as shown in FIG. 2, load lock chamber 102 includes two robot arms 114. Using more than one robot arm 114 in load lock chamber 102 may increase a maximum throughput (the number of substrates processed per unit of time (e.g., substrates processed per hour)) possible for processing substrates in apparatus 100. Additionally, apparatus 100 may still be operational if one robot arm fails as the additional robot arms may be used to compensate for the failed robot arm.

In certain embodiments, robot arms 114 are multi-axis robot arms (e.g., robot arms that can move in three-dimensional paths). In certain embodiments, robot arms 114 have at least 6 degrees of freedom. In some embodiments, robot arms 114 have at least 3 degrees, at least 4 degrees, or at least 5 degrees of freedom. In certain embodiments, robot arms 114 may have up to, but not limited to, 12 degrees of freedom. Examples of commercially available multi-axis robot arms are an LR Mate 200iB and an M-6iB available from FANUC Robotics American, Inc. (Rochester Hills, Mich. (USA)).

The movement of robot arms 114 is controlled by robotic controllers 116. In certain embodiments, robotic controllers 116 are controllers specifically designed for control of robot arms 114. For example, robotic controllers 116 may be obtained in a packaged system along with robot arms 114. Robotic controllers 116 may be coupled to a process control system for apparatus 100. The process control system may control the movement of substrates in load lock chamber 102 and directs the movement of substrates between the load lock chamber and both substrate loading chamber 112 and substrate transfer chamber 104 by controlling the movement of robot arms 114.

In certain embodiments, robot arms 114 and/or robotic controllers 116 include or are coupled to rails 117. FIG. 4 depicts a representation of an embodiment of robot arm 114 and robotic controller 116 on rail 117. Rail 117 allows for translational movement of robot arm 114 and/or robotic controller 116. Robot arm 114 and/or robotic controller 116 may slide back and forth along rail 117. In certain embodiments, the process control system controls the movement of robot arm 114 and/or robotic controller 116 along rail 117 along with the movement of the robot arm to control the movement of substrates in load lock chamber 102 and the movement of substrates into substrate transfer chamber 104 from the load lock chamber, as shown in FIGS. 1A and 2.

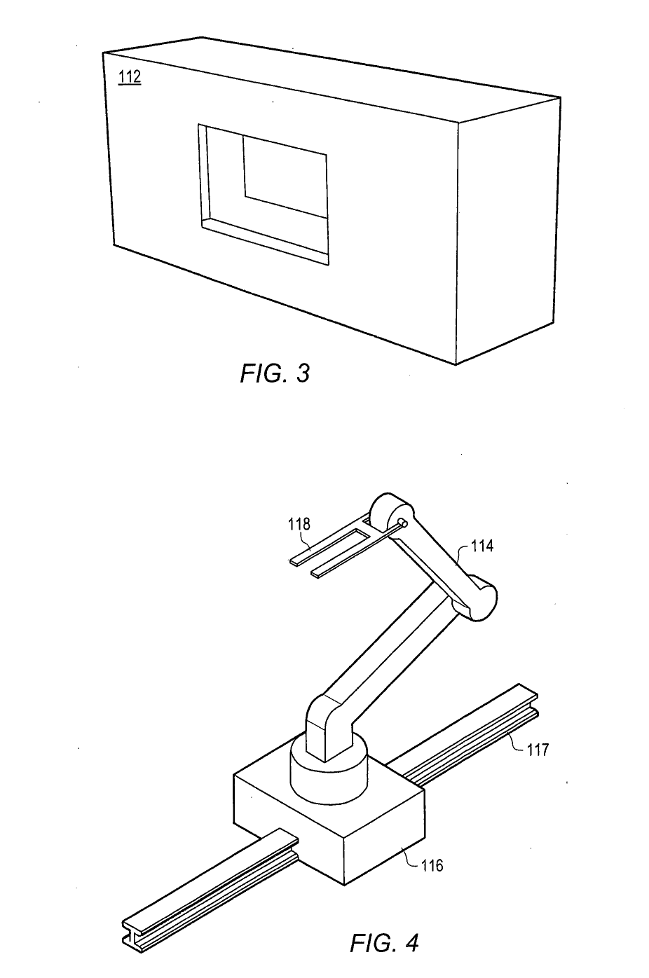

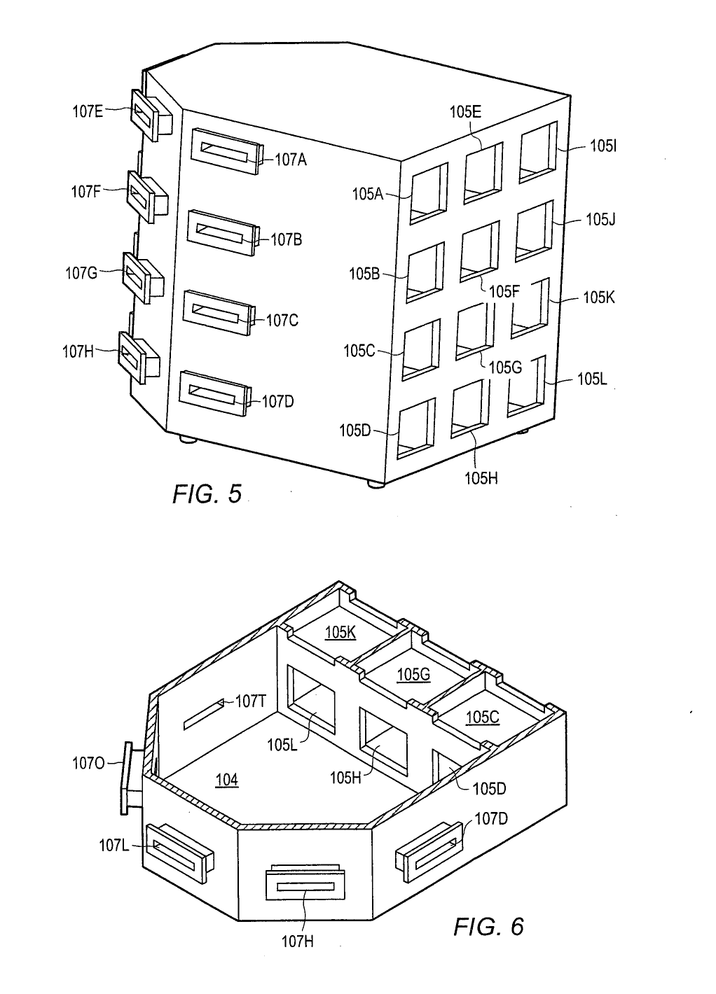

In certain embodiments, substrates and/or substrate carriers are stored in substrate transfer chamber 104. As shown in FIGS. 1A and 2, substrates and/or substrate carriers may be stored in storage bays 105. FIG. 5 depicts an end view representation of substrate transfer chamber 104 with twelve storage bays 105A-L. FIG. 6 depicts a top view schematic representation of substrate transfer chamber 104 showing storage bays 105C, 105D, 105G, 105H, 105K, and 105L. Any number of storage bays may be used in substrate transfer chamber 104 depending on, for example, a desired substrate throughput for apparatus 100. Substrates and/or substrate carriers are placed in an appropriate storage bay by robot arms 114 in load lock chamber 102, shown in FIGS. 1A and 2. The appropriate storage bay may be any storage bay 105A-L selected by, for example, a process control system used to control apparatus 100. Substrates and/or substrate carriers may be stored in storage bays 105A-L until the substrates and/or substrate carriers are moved to process chamber modules 106 or are removed from apparatus 100 through load lock chamber 102 and substrate loading chamber 112, as shown in FIGS. 1A and 2. The system of storing substrates and/or substrate carriers in storage bays 105A-L using load lock chamber 102 and substrate loading chamber 112 may be referred to as a “load lock stocker” system.

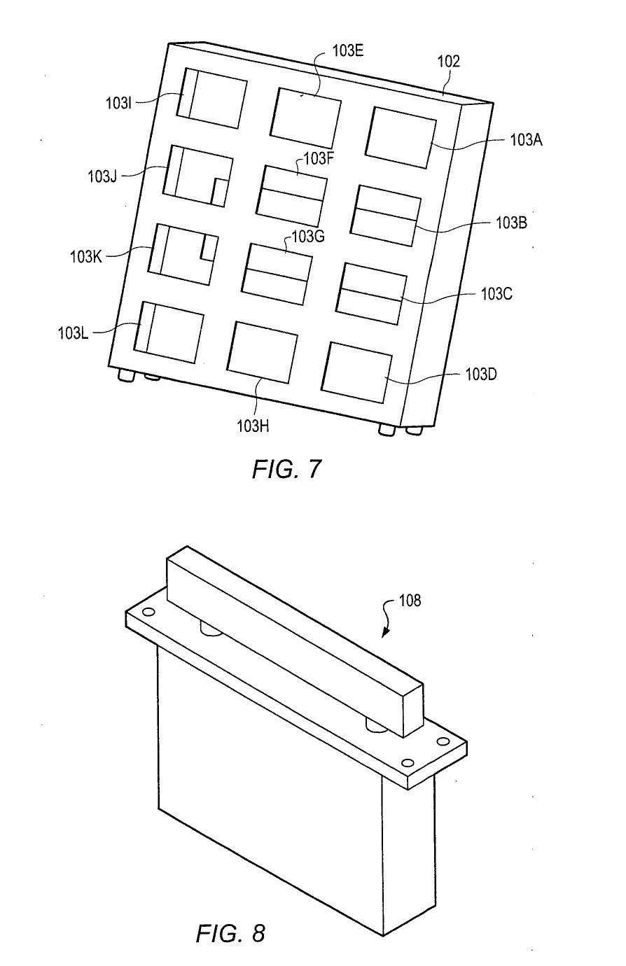

As shown, in FIGS. 5 and 6, storage bays 105 may have openings at each end with one opening coupling to load lock chamber 102 and one opening coupling to substrate transfer chamber 104. Load lock chamber 102 may have openings 103A-L, as shown in FIG. 7. Openings 103A-L may align with corresponding openings of storage bays 105A-L.

As shown in FIGS. 1A, 2, 5, and 6 storage bays 105 may be located in substrate transfer chamber 104. One or more valves (e.g., gate valves) may be coupled between openings on storage bays 105 and load lock chamber 102. At least one valve may be closed to vacuum isolate one or more storage bays 105 from load lock chamber 102.

In some embodiments, one valve is closed to vacuum isolate all storage bays 105 from load lock chamber 102 and vacuum isolate the load lock chamber and substrate transfer chamber 104. In some embodiments, valves are individually coupled to an opening of each storage bay and the valves are operated individually to vacuum isolate each storage bay from load lock chamber 102. In embodiments with individual valves, all the individual valves are closed to vacuum isolate load lock chamber 102 and substrate transfer chamber 104. In some embodiments, two or more valves are grouped together and operate together to vacuum isolate one or more storage bays from load lock chamber 102. In some embodiments, one valve may operate to vacuum isolate two or more storage bays.

In some embodiments, load lock chamber 102 includes mechanisms for storing substrates and/or substrate carriers. Substrates and/or substrate carriers may be stored in load lock chamber 102 until the substrates and/or substrate carriers are moved to substrate transfer chamber 104, moved to process chamber modules 106, or removed from apparatus 100 through substrate loading chamber 112. In some embodiments, storage bays 105 may be located in load lock chamber 102. In such embodiments, one or more valves (e.g., gate valves) may be coupled between openings on storage bays 105 and substrate transfer chamber 104. At least one valve may be closed to vacuum isolate one or more storage bays 105 from substrate transfer chamber 104. One valve or several individual valves may be closed to vacuum isolate load lock chamber 102 and substrate transfer chamber 104 as described above.

As shown in FIGS. 1A and 2, load lock chamber 102 is vacuum coupled to substrate transfer chamber 104. Load lock chamber 102 is vacuum coupled to substrate transfer chamber 104 so that substrates may be transferred between the chambers under sub-atmospheric conditions. In some embodiments, one or more valves (e.g., one or more valves coupled to openings of storage bays 105A-L) are coupled between load lock chamber 102 and substrate transfer chamber 104. At least one of the valves may be closed to vacuum isolate load lock chamber 102 and substrate transfer chamber 104. Load lock chamber 102 and substrate transfer chamber 104 may be vacuum isolated so that, for example, either of the chambers may be cleaned, repaired, and/or replaced. One of the chambers may be cleaned, repaired, and/or replaced without affecting sub-atmospheric conditions in the other chamber because of the vacuum isolation between the chambers.

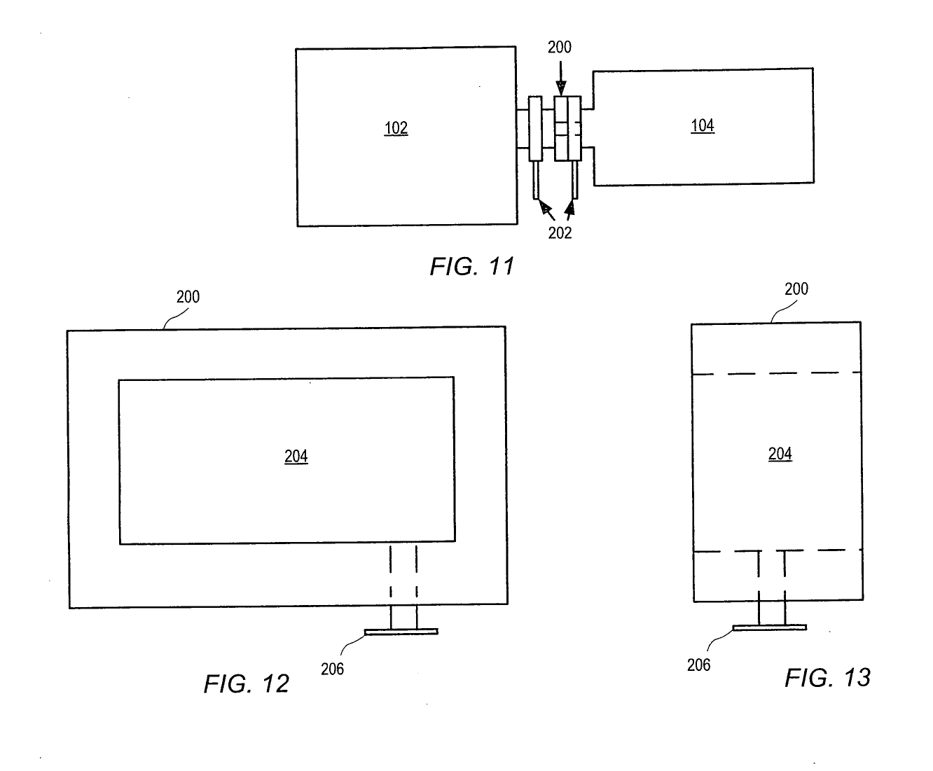

In certain embodiments, as shown in FIG. 11, vacuum curtain 200 is located between substrate transfer chamber 104 and load lock chamber 102. Vacuum curtain 200 is vacuum coupled to substrate transfer chamber 104 and load lock chamber 102. Substrates may pass (under sub-atmospheric conditions) through vacuum curtain 200 as substrates are transferred between substrate transfer chamber 104 and load lock chamber 102. Vacuum curtain 200 may be located between isolation valves 202. Isolation valves 200 may be used to vacuum isolate substrate transfer chamber 104. load lock chamber 102, and/or vacuum curtain 200. In some embodiments, more than one vacuum curtain 200 is located between substrate transfer chamber 104 and load lock chamber 102.

FIG. 12 depicts a front view representation of an embodiment of vacuum curtain 200. FIG. 13 depicts a side view representation of vacuum curtain 200. Vacuum curtain 200 includes opening 204. Opening 204 allows substrates to pass through vacuum curtain 200. Opening 204 also allows substrate transfer chamber 104 to be vacuum coupled to load lock chamber 102 through vacuum curtain 200. In certain embodiments, opening 204 is vacuum coupled to a vacuum source (e.g., a vacuum pump) through port 206.

In certain embodiments, the vacuum source coupled to vacuum curtain 200 is used to produce a pressure in the vacuum curtain that is lower than a pressure in substrate transfer chamber 104 and/or load lock chamber 102. The pressure in vacuum curtain 200 may be maintained at a lower pressure than substrate transfer chamber 104 and/or load lock chamber 102 so that any contamination (e.g., particulates or chemical contamination) is removed in the vacuum curtain (e.g., by the vacuum source) when the vacuum curtain is open to the substrate transfer chamber and/or the load lock chamber. The lower pressure in vacuum curtain 200 may be able to remove any contamination on any objects that pass through the vacuum curtain. For example, contamination robot arms, end effectors, and/or substrates may be removed in vacuum curtain 200.

Operation of vacuum curtain 200 and the vacuum source coupled to the vacuum curtain (e.g., vacuum pumping and/or pressure in the vacuum curtain) may be controlled and/or monitored by a process control system coupled to apparatus 100. For example, the process control system may control the vacuum source to maintain a desired pressure in vacuum curtain 200. The process control system may also control other components (e.g., valves 202 or vent valves on the vacuum curtain) to control the pressure in vacuum curtain 200. In some embodiments, vacuum curtain 200 is continuously vacuum pumped to maintain a vacuum in the vacuum curtain (e.g., the vacuum source is continuously operated). The process control system may monitor the pressure in vacuum curtain 200 and make adjustments if the pressure changes or needs to be changed due to changes in processing parameters in apparatus 100. In some embodiments, the vacuum source is operated to provide vacuum in vacuum curtain 200 only as needed during operation of apparatus 100. For example, the vacuum source is turned on/off as needed to provide vacuum in vacuum curtain 200 (e.g., before and during the time the vacuum curtain is vacuum coupled to substrate transfer chamber 104 and/or load lock chamber 102).

The pressure in vacuum curtain 200 may be controlled, as needed, to be higher or lower than the pressure in substrate transfer chamber 104 and/or load lock chamber 102. For example, certain process parameters may require the pressure in vacuum curtain 200 to be lower than the pressure in substrate transfer chamber 104 and/or load lock chamber 102 while other process parameters may require the pressure in the vacuum curtain to be higher than the pressure in the substrate transfer chamber and/or the load lock chamber. The process control system may vary the pressure in vacuum curtain 200 according to the proper process parameters.

In some embodiments, the pressure in vacuum curtain 200 (or the amount of vacuum pumping by the vacuum source) is selected to control a pressure differential between substrate transfer chamber 104 and load lock chamber 102. For example, the pressure differential between substrate transfer chamber 104 and load lock chamber 102 may need to be controlled during a soft-start (e.g., slow startup to steady state conditions) of apparatus 100.

In some embodiments, vacuum curtain 200 includes a gas inlet port. The gas inlet port may be used to provide a gas into vacuum curtain 200. In some embodiments, the gas is used for additional pressure control in vacuum curtain 200 by controlling flow of a gas into the vacuum curtain. In some embodiments, the gas is used to purge vacuum curtain 200 and/or other components coupled to the vacuum curtain (e.g., substrate transfer chamber 104, load lock chamber 102, and/or valves 202). In certain embodiments, the gas is an inert gas such as nitrogen or argon. In some embodiments, other gases such as cleaning gases (e.g., oxygen) are provided to vacuum curtain 200. In some embodiments, vacuum curtain 200 includes electrodes or other components that may be used to generate a plasma in the vacuum curtain. For example, the electrodes may be used to generate a cleaning plasma in the vacuum curtain.

In some embodiments, one or more vacuum curtains 200 are located between other chambers in apparatus 100. For example, one or more vacuum curtains 200 may be located between substrate transfer chamber 104 and process chambers 106 and/or between load lock chamber 102 and substrate loading chamber 112. Isolation valves may also be located on one or both sides of these additional vacuum curtains.

Substrate transfer chamber 104 includes mechanisms and/or devices for transferring substrates between storage bays 105A-L and process chamber modules 106A-T. In certain embodiments, substrate transfer chamber 104 includes one or more robot arms 114 for transferring substrates between storage bays 105A-L and process chamber modules 106A-L and between individual process chamber modules.

In an embodiment, as shown in FIGS. 1A and 2, substrate transfer chamber 104 includes two robot arms 114. In some embodiments, one or more robot arms 114 are dedicated for transferring substrates in or between certain areas of apparatus 100. As one example, as shown in FIG. 2, a first robot arm may be used for transferring substrates in an upper half of substrate transfer chamber 104 while a second robot arm is used for transferring substrates in a lower half of the substrate transfer chamber. As another example, a first robot arm may be used for transferring substrates between process chamber modules 106A-T while a second robot arm is used for transferring substrates between storage bays 105A-L and the process chamber modules.

Using more than one robot arm 114 in substrate transfer chamber 104 may increase a maximum throughput (the number of substrates processed per unit of time (e.g., substrates processed per hour)) possible for processing substrates in apparatus 100. Additionally, apparatus 100 may still be operational if one robot arm fails as the additional robot arms may be used to compensate for the failed robot arm.

Robot arms 114 may be used to transfer substrates back and forth between storage bays 105A-L and process chamber modules 106A-T as well as between individual process chamber modules. The movement of robot arms 114 is controlled by robotic controllers 116. Robotic controllers 116 may be coupled to a process control system for apparatus 100. The process control system controls the movement of substrates within apparatus 100 according to the current substrate processing protocols for the apparatus (e.g., type of substrate processing or order of substrate processing). For example, the process control system may assess which storage bays 105A-L the substrates should be taken from or which storage bays the substrates should be placed in after processing.

In certain embodiments, robot arms 114 and/or robotic controllers 116 include or are coupled to rails 117, as shown in FIGS. 1A, 2, and 4. Robot arm 114 and/or robotic controller 116 may slide back and forth along rail 117. In certain embodiments, the process control system controls the movement of robot arm 114 and/or robotic controller 116 along rail 117 along with the movement of the robot arm to control the movement of substrates in substrate transfer chamber 104 and the movement of substrates into and out of storage bays 105A-L, as shown in FIGS. 1A and 2.

As shown in FIG. 4, robot arm 114 may include end effector 118 to couple the robot arm to a substrate. End effector 118 may include mechanisms and/or devices for coupling and uncoupling the substrate from robot arm 114. Examples of end effectors include, but are not limited to, trays, slots, and captive mechanisms. In certain embodiments, end effector 118 cannot rely on gravity to hold on to the substrate during transfer so a captive mechanism end effector is needed for substrate transfer. Captive mechanism end effectors include, but are not limited to, grasping mechanisms, such as substrate clamps or substrate tweezers, and vacuum mechanisms, such as vacuum chucks. In some embodiments, end effector 118 may include additional substrate tools such as, but not limited to, substrate cleaning devices and substrate heating devices. For example, end effector 118 may include a heater to maintain a substrate temperature during transfer of the substrate between two process chamber modules.

End effectors 118 may be chosen based on, for example, the types of processes used in process chamber modules 106A-T. Process issues may also be taken into consideration when choosing end effectors 118. Process issues that may be taken into consideration include, but are not limited to, effluent isolation (e.g., isolation of byproducts that may poison other chambers), particle minimization (e.g., inhibiting particulate matter from falling off substrates or transfer arms), turbulent flow minimization, and speed of wafer transport (e.g., minimizing delays for transport). For example, end effectors used for dry chemical processes may not be compatible with end effectors used for wet chemical processes and vice versa.

As shown in FIGS. 1A and 2, substrate transfer chamber 104 may be vacuum coupled to process chamber modules 106A-T. In certain embodiments, substrate transfer chamber 104 and process chamber modules 106A-L are under sub-atmospheric conditions while apparatus 100 is in operation (e.g., while the apparatus is processing substrates). Valves 108A-T may be coupled to corresponding openings 107A-T, shown in FIGS. 5 and 6. Valves 108A-T may couple process chamber modules 106A-T to substrate transfer chamber 104 at openings 107A-T.

Valves 108A-T may be closed to vacuum isolate process chamber modules 106A-T from substrate transfer chamber 104. Valves 108A-T may be, for example, gate valves or vacuum isolation valves. An example of a slit type gate valve is shown in FIG. 8. As depicted in FIGS. 1A and 2, valves 108A-T may be opened for transfer of substrates into and out of process chamber modules 106A-T. Valves 108A-T are closed during substrate processing in process chamber modules 106A-T. In certain embodiments, valves 108A-T operate independently to allow independent operation of process chamber modules 106A-T. In addition, valves 108A-T may be closed to vacuum isolate individual process chamber modules 106A-T from substrate transfer chamber 104 so that the vacuum isolated process chamber modules may be cleaned, repaired, replaced, and/or removed from apparatus 100. The process chamber modules may be cleaned, repaired, and/or replaced without affecting sub-atmospheric conditions in substrate transfer chamber 104 because of the vacuum isolation of the process chamber modules. Process chamber modules may be vacuum isolated to inhibit or reduce problems associated with process issues such as, but not limited to, effluent isolation (e.g., isolation of byproducts that may poison other chambers), particle minimization (e.g., inhibiting particulate matter from falling off substrates or transfer arms), turbulent flow minimization, and speed of wafer transport (e.g., minimizing delays for transport).

Apparatus 100 includes a plurality of process chamber modules 106A-T. In certain embodiments, process chamber modules 106A-T are both horizontally clustered around substrate transfer chamber 104 and vertically stacked. For example, as shown in FIG. 1, process chamber modules 106A-T may be arranged in a horizontal cluster of five vertical stacks around substrate transfer chamber 104 (stack 1 is modules 106A-D; stack 2 is modules 106E-H; stack 3 is modules 106I-L, stack 4 is modules 106M-P, and stack 5 is modules 106Q-T). A vertical stack is a substantially vertical stack or tower of two or more process chamber modules with one process chamber module above another process chamber module. For example, stack 3 with four process chamber modules 106I-L is shown in FIG. 2.

In certain embodiments, a stack of process chamber modules are located in a support structure (e.g., an equipment rack). Process chamber modules may be easily placed into and/or removed from the support structure. For example, the process chamber modules may slide in rails on the support structure. In some embodiments, the process chamber modules may be moved in the support structure, at least in part, using hydraulics, electric motors, wenches, and/or other means for moving heavy equipment. For example, a process chamber module may be isolated from the substrate transfer chamber, decoupled from the substrate transfer chamber, and moved away from the substrate transfer chamber in the support structure using hydraulics. Transport devices such as, but not limited to, hydraulic lifts, forklifts, and/or cranes may be used to transport process modules to and from the support structure and the apparatus.

The number of vertical stacks of process chamber modules horizontally clustered around substrate transfer chamber 104 may vary depending on, for example, the amount of work space (e.g., cleanroom space) available, the size of the substrate transfer chamber, a desired number of process chamber modules, the number of ports on the substrate transfer chamber, costs for work space, a factory's requirements (e.g., substrate throughput), future technology or capacity requirements, support equipment size, space available for support equipment, operational logistics in the factory, manpower requirements, and/or serviceability of the process chamber modules. In one embodiment, five vertical stacks are horizontally clustered around the substrate transfer chamber. In some embodiments, two, three, or four vertical stacks are horizontally clustered around the substrate transfer chamber. In some embodiments, six or more vertical stacks are horizontally clustered around the substrate transfer chamber.

The number of process chamber modules in a vertical stack clustered around substrate transfer chamber 104 may vary depending on, for example, a ceiling or amount of vertical height available, the amount of work space (e.g., cleanroom space) available, the size of the substrate transfer chamber, a desired number of process chamber modules, the number of ports on the substrate transfer chamber, costs for work space, a factory's requirements (e.g., substrate throughput), future technology or capacity requirements, support equipment size, space available for support equipment, operational logistics in the factory, manpower requirements, and/or serviceability of the process chamber modules. In one embodiment, four process chamber modules are in a vertical stack horizontally clustered around the substrate transfer chamber. In some embodiments, two or three process chamber modules are in a vertical stack horizontally clustered around the substrate transfer chamber. In some embodiments, five or more process chamber modules are in a vertical stack horizontally clustered around the substrate transfer chamber.

The number of vertical stacks, the number of process chamber modules in a vertical stack, and/or the configuration of the vertical stacks and process chamber modules may vary based on, for example, user (e.g., customer) considerations or other process considerations. The number of vertical stacks and process chamber modules may also affect the size and/or configuration of other portions of apparatus 100 (e.g., load lock chamber 102, substrate loading chamber 112, and substrate transfer chamber 104).

Arranging process chamber modules 106A-T in a plurality of horizontally clustered vertical stacks, as shown in FIGS. 1, 1A, and 2, may increase standard substrate processing throughput for processing substrates in apparatus 100 versus a cluster tool apparatus with a similar horizontal dimensions and without vertical stacking because of the increased number of process chamber modules. In certain embodiments, arranging process chamber modules 106A-T in a plurality of horizontally clustered vertical stacks increases the wafer throughput per square foot of floor space (e.g., cleanroom floor space). Increasing the substrate processing throughput and using less floor space may reduce the cost per substrate produced. Substrate processing throughputs may be affected, either adversely or beneficially, by processing requirements (e.g., what types of processes are being performed and delay times required between substrate processes). In certain embodiments, apparatus 100 has a standard substrate processing throughput of at least 300 substrates per hour, at least 400 substrates per hour, or at least 500 substrates per hour. In certain embodiments, apparatus 100 processes substrates at a throughput that is within 1%, within 5%, or within 10% of a throughput of a process chamber module operating at steady state (e.g., operating continuously).

Process chamber modules 106A-T may perform a variety of substrate processes. Process chamber modules 106A-T may perform substrate processes such as, but not limited to, thin film deposition, chemical vapor deposition (CVD), physical vapor deposition (PVD), atomic layer deposition (ALD), etching processes (e.g., reactive ion etching (RIE), plasma etching, reactive ion beam etching (RIBE)), rapid thermal processing (RTP), wet or dry stripping processes, annealing processes, diffusion processes, insulator (e.g., polyimide) deposition processes, film irradiation processes, metrology or substrate inspection processes, and other doping, epitaxy, or removal processes. Process chamber modules 106A-L may be designed to perform current substrate processes and/or newly developed substrate processes. In some embodiments, process chamber modules 106A-L include process chambers provided by standard equipment suppliers (e.g., semiconductor process chambers available from Applied Materials, Inc. (Santa Clara, Calif., USA) or Novellus Systems, Inc. (San Jose, Calif., USA)).

The types and number of substrate processes to be performed in process chamber modules 106A-T may be selected depending on user's needs such as, but not limited to, work space, technology, substrate capacity, process capabilities, and manufacturing costs. In certain embodiments, process chamber modules 106A-T are configured to perform a combined process on a substrate (e.g., one or more substrates go through all or most of the process chamber modules to provide one end product from the apparatus). In some embodiments, apparatus 100 performs several different substrate processes (e.g., a first group of process chamber modules produces a first end product while a second group of process chamber modules produces a second end product). In some embodiments, apparatus 100 performs with groups of process chamber modules processing substrates in parallel substrate processes (e.g., a first group of process chamber modules produces an end product while a second group of process chamber modules produces the same end product in parallel to the first group). In some embodiments, apparatus 100 performs a combination of two or more of the above described embodiments for processing substrates.

In certain embodiments, process chamber modules 106A-T are cycle-purged. Cycle-purging may inhibit cross-contamination between process chamber modules running different substrate processes by isolating and/or removing cross-contaminants in apparatus 100. Apparatus 100 may allow for cycle-purging of process chamber modules 106A-T without reducing the substrate processing throughput of the apparatus.

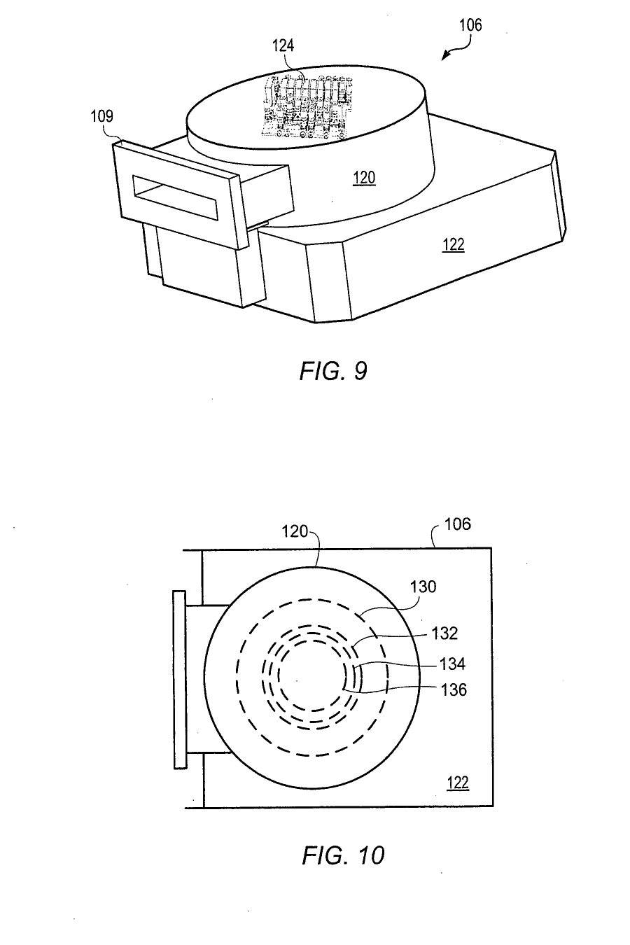

FIG. 9 depicts a representation of an embodiment of process chamber module 106. In certain embodiments, process chamber module 106 includes process chamber 120 and support module 122. Opening 109 may open into process chamber 120. Opening 109 may couple process chamber module 106 to a corresponding opening 107 on substrate transfer chamber 104, shown in FIGS. 5 and 6. Valve 108, depicted in FIG. 8, may be used to couple opening 109 to opening 107.

Process chamber module 106, depicted in FIG. 9, may be used to process substrates (e.g., semiconductor substrates). Substrates are processed in process chamber 120 (e.g., CVD, PVD, or ALD may be performed in the process chamber for semiconductor substrates). Process chamber 120 may be designed to perform current substrate processes and/or newly developed substrate processes. Support module 122 may include components used to support process chamber 120 and the process performed in the process chamber. Examples of components that may be in support module 122 include, but are not limited to, gas lines, water lines, vacuum lines, process control electronics, power supplies, interfaces for exhaust, direct support for exhaust, abatement, process cooling and/or heating, bulk chemical supplies and/or interfaces, doping sources, RF or microwave generators, bias generators, electronic monitoring equipment, and communication hardware and/or software.

In certain embodiments, process chamber module 106 includes chemical management system 124. In certain embodiments, chemical management system 124 is a gas manifold. Chemical management system 124 includes gas or chemical processing components (e.g., gas lines, mass flow controllers, flow control valves, and gas process control electronics) needed for providing chemicals (e.g., gas) to process chamber 120. In certain embodiments, chemical management system 124 includes surface mount components. Examples of surface mount components may be found in U.S. Pat. No. 6,394,138 to Vu et al., U.S. Pat. No. 6,302,141 to Markulec et al., U.S. Pat. No. 6,125,887 to Pinto, U.S. Pat. No. 6,298,881 to Curran et al., U.S. Pat. No. 6,415,822 to Hollingshead, U.S. Pat. No. 6,629,546 to Eidsmore et al, and U.S. Pat. No. 6,474,700 to Redemann et al., each of which is incorporated by reference as if fully set forth herein. Other modular chemical management systems known in the art may also be used in chemical management system 124.

In certain embodiments, chemical management system 124 is directly connected to process chamber 120. Chemical management system 124 may be, for example, directly connected to an outer surface of process chamber 120. The outer surface of process chamber 120 includes any surface on the outside of the process chamber (e.g., the upper or lower outer surface of the process chamber). In one embodiment, chemical management system 124 includes a plate mounted and directly connected to an upper outer surface of process chamber 120, as shown in FIG. 9. In some embodiments, chemical management system 124 includes a plate that is constructed as part of process chamber 120 so that the chemical management system is directly connected to the outer surface of the process chamber. In certain embodiments, chemical management system 124 is removable from process chamber 120 so that the chemical management system may be cleaned, repaired, and/or replaced. For example, chemical management system 124 may be coupled (e.g., directly connected) to process chamber 120 using bolts or other removable fastening devices.

Directly attaching chemical management system 124 to process chamber 120 may reduce the lead-time for gases to enter the process chamber because of the proximity of the chemical management system. The reduced lead-time may reduce reaction times to changes in gas flow in process chamber 120 and improve process control in the process chamber. Directly attaching chemical management system 124 to process chamber 120 may also reduce the amount of gas piping needed in apparatus 100. The reduced amount of piping may be more reliable as compared to apparatus with large amounts of piping, which increases the chances of leaks or other failures.

In certain embodiments, process chamber module 106 includes process chamber 120, support module 122, chemical management system 124, and/or valve 108 in a self-contained module. Process chamber 120 is coupled to support module 122, chemical management system 124, and/or valve 108 so that process chamber module 106 may be installed and removed from apparatus 100, shown in FIGS. 1, 1A, and 2, as an independent module. Each individual process chamber module 106A-T, shown in FIGS. FIGS. 1, 1A, and 2, may include a single process chamber 120 with a dedicated support module 122, dedicated chemical management system 124, and/or dedicated valve 108 for the single process chamber. Each process chamber module 106A-T may operate independently from any other process chamber module. Thus, individual process chamber modules 106A-T may be vacuum isolated from substrate transfer chamber 104 using valves 108A-T, shown in FIGS. 1A and 2, and disconnected or removed from the substrate transfer chamber without disrupting other process chamber modules or other chambers or components in apparatus 100. Process chamber modules may be removed from apparatus 100 for maintenance, repair, replacement, and/or engineering assessment (e.g., process condition assessment). In certain embodiments, process chamber modules are qualified for operation before the process chamber modules are installed on apparatus 100. Process chamber modules may be qualified for operation by preparing the process chamber modules (e.g., seasoning and/or pre-qualification) and/or testing the operation of the process chamber modules in, for example, a machine shop.

Process chamber modules 106A-T may be referred to as “plug-n-play” modules. Process chamber modules 106A-T may be disconnected and/or removed from substrate transfer chamber 104 so that the process chamber modules may be cleaned, repaired, and/or replaced. Having “plug-n-play” process chamber modules 106A-T on apparatus 100 allows for simple and easy replacement of process chamber modules so that the apparatus may be easily reconfigured if desired by the user. Process chamber modules 106A-T may be mixed and matched by the user to suit his/her needs at any point in time.

In certain embodiments, apparatus 100 is able to process substrates (e.g., semiconductor substrates) with a variety of sizes (e.g., a variety of diameters). Apparatus 100 may “bridge” (e.g., be backward and forward compatible with) substrate sizes between, for example, 100 mm and 450 mm. In certain embodiments, apparatus 100 is able to process substrates with sizes such as, but not limited to, 100 mm, 150 mm, 200 mm, 300 mm, and 450 mm. Other sizes of substrates may also be contemplated for processing in apparatus 100. For example, processes may be developed for processing a substrate size greater than 450 mm and apparatus 100 may be adapted to process the larger substrate size. The size or diameter of the substrates to be processed may be selected, for example, by a user of apparatus 100. The user may be a substrate manufacturer or other end user of the apparatus. In some embodiments, apparatus 100 is initially designed or constructed to process substrates of one size (e.g., 300 mm) and is later adjusted or adapted to process substrates of another size (e.g., 200 mm).

In certain embodiments, one or more components of apparatus 100 are physically adjusted or adapted to be able to process substrates of varying sizes. Components that may be adjusted or adapted to allow apparatus 100 to process substrates of varying sizes include, but are not limited to, robot arms, end effectors of robot arms, substrate carriers, process chamber dimensions, and process chamber components such as substrate holders, gas shower heads, plasma electrodes, load lock chamber components, cassette interfaces, chamber interfaces and gate valves, gas manifolds, power supplies, RF or microwave generators, and bias generators. Chamber inserts or other drop-in type components may be used to adapt the apparatus to handle and process various substrate sizes.

FIG. 10 depicts an example of a variable size substrate holder in process chamber 120. Process chamber 120 may have a maximum substrate size of 450 mm (ring 130). Inserts such as discs or jigs may be used to reduce the substrate holder size to smaller substrate sizes such as 300 mm (ring 132), 200 mm (ring 134), or 100 mm (ring 136).

In certain embodiments, chamber inserts or other means are used to reduce or alter a volume of a process chamber. For example, a smaller or different volume may be needed to process a substrate of a smaller size in a vapor deposition environment to inhibit end effects or other gas flow inconsistencies. In addition, substrate processing parameters such as gas flowrates, plasma powers, processing times, process pressures, and process temperatures may be adjusted to compensate for a change in substrate size. Other factors that may be considered in adapting apparatus 100 and/or process chamber modules 106A-T when changing the substrate size include, but are not limited to, field effects for electromagnetic fields, temperature effects and uniformities, power distribution of gate oxide impacts and related device impacts, surface areas for maintenance and particle management, process uniformities, bias effects, voltages, gas flow effects, chemical flow effects, and temperature ramp rates.

In certain embodiments, apparatus 100 is configured to process substrates of two or more substrate sizes (e.g., 200 mm and 300 mm substrates, or 300 mm and 450 mm substrates, may be processed in the apparatus during the same time period (e.g., substantially simultaneously)). Having apparatus 100 process substrates of two or more substrate sizes during the same time period may allow a user to process multiple substrate sizes during a transition or development phase of the apparatus.

In certain embodiments, process chamber modules that process a first substrate size are swapped with process chamber modules that process a second substrate size to adjust the substrate size processed by apparatus 100, shown in FIGS. 1, 1A, and 2. The process chamber modules may be swapped within apparatus 100 without disrupting other components or chambers of the apparatus. In some embodiments, process chamber modules for the second substrate size are phased into apparatus 100 over a period of time. For example, a first substrate process at one substrate size may continue to operate as process chamber modules not used in the first substrate process are swapped out with process chamber modules for processing the second substrate size.

In certain embodiments, apparatus 100 may be designed for a maximum contemplated substrate size desired by the user. Apparatus 100 may then be reconfigured for a smaller substrate size to be initially used by the user. Thus, at later times, the user may reconfigure apparatus 100 to process substrates of any size less than the maximum contemplated size.

In certain embodiments, apparatus 100 is coupled to a process control system. The process control system may be used to interface with, manage, and coordinate systems (e.g., control systems) associated with components in apparatus 100. The process control system may interface with, manage, and coordinate systems such as, but not limited to, process chamber module control systems, load lock control systems, robot arm control systems, user interface systems, and factory floor work in progress (WIP) management systems. User interface systems include, but are not limited to, engineer interface systems, operator interface systems, technician interface systems, and manager interface systems. In some embodiments, the process control system interfaces with control systems that are packaged with individual components in the apparatus. For example, the process control system may interface with a control system that is packaged with a process control module or a robotic control system that is packaged with a robotic controller.

In certain embodiments, the process control system manages and coordinates individual systems utilized in apparatus 100 to produce a desired result from the apparatus. For example, the process control system may manage apparatus 100 and coordinate process chamber modules 106A-T to produce a desired end condition or desired end product for one or more substrates. In certain embodiments, the process control system controls and monitors multiple substrate processes in apparatus 100. In some embodiments, the process control system assesses (e.g., tracks) and coordinates the movement of substrates within the apparatus. For example, the process control system may automatically control the transfer of substrates between the load lock and the process chambers; the transfer of substrates between process chambers; and/or the operation of the process chambers.

The process control system may utilize automatic process control (APC) in managing and controlling apparatus 100. The process control system may control process parameters such as, but not limited to, process power, wafer bias, process times, process temperatures, and process pressures. In certain embodiments, the process control system may control process parameters in a “feed forward” manner. Feed forward process control includes, for example, controlling process parameters based on input from substrate processes performed before the current process, material properties, and/or measurements made prior to the substrate entering the current process chamber module. In certain embodiments, the process control system may control process parameters in a “feed back” manner. Feed back process control includes, for example, controlling process parameters based on assessments and/or measurements (e.g., metrology measurements) made after the substrate is processed by the current process chamber module.

In certain embodiments, the process control system monitors the status of process chamber modules to let a user know when modules need repair and/or replacement. In certain embodiments, the process control system allows the user (e.g., through a user interface) to shut down one or more components (e.g., one or more process chamber modules) in apparatus 100 for maintenance, repair, replacement, and/or engineering assessment (e.g., process parameter assessment). Shutting down a component includes, but is not limited to, isolating the component (e.g., vacuum isolating the component), powering down the component, pumping down the component, and purge the component (e.g., with inert gas). For example, a process chamber module may be isolated from the apparatus by the process control system so that the process chamber module can be removed from the apparatus. Maintenance, repair, and/or engineering assessments may be performed on the removed process chamber module.

The process control system may automatically reconfigure the apparatus to compensate for the removed process chamber module if a new process chamber module is not installed. Reconfiguring the apparatus allows the apparatus to continue to run while the process chamber module is removed from the apparatus.

In certain embodiments, the process control system performs diagnostic assessment of one or more components (e.g., process chamber modules) in the apparatus while the apparatus is processing substrates. For example, the process control system may include in situ monitoring of the plasma discharges and/or in situ analysis of the effluent from the process chamber modules. Plasma discharge monitoring may include, for example, plasma discharge wavelength analysis. Plasma discharge wavelength analysis may be used to monitor the processes to inhibit cross-contamination and/or other problems such as, but not limited to, leaks, gas contamination, wafer contamination, and particulate generation.

In some embodiments, the process control system performs maintenance on one or more components while the apparatus is processing substrates. In some embodiments, the process control system performs engineering assessments of one or more components while the apparatus is processing substrates.

Each of the following patents is incorporated by reference as if fully set forth herein: U.S. Pat. Nos. 4,232,063; 4,668,365; 4,731,255; 4,794,019; 5,028,565; 5,043,299; 5,133,284; 5,207,836; 5,230,741; 5,238,499; 5,272,880; 5,292,554; 5,304,248; 5,326,725; 5,328,722; 5,362,526; 5,374,594; 5,384,008; 5,413,669; 5,440,887; 5,425,803; 5,476,548; 5,508,067; 5,516,367; 5,556,476; 5,578,532; 5,620,525; 5,645,625; 5,662,143; 5,667,592; 5,778,969; 5,791,895; 5,806,980; 5,810,933; 5,814,154; 5,900,105; 5,928,426; 5,944,940; 5,984,391; 6,007,675; 6,082,297; 6,126,382; 6,143,082; 6,167,893; 6,179,973; 6,190,103; 6,199,506; 6,200,412; 6,224,680; 6,319,553; 6,342,133; 6,375,746; 6,405,101; 6,431,807; 6,444,105; 6,468,384; 6,468,404; 6,471,831; 6,497,734; 6,497,796; 6,553,933; 6,560,507; 6,563,092; 6,602,346; 6,616,985; 6,665,584; 6,682,295; 6,712,907; 6,722,665; 6,722,835; 6,753,689; 6,758,591; 6,761,085; 6,778,762; and 6,800,173.

In this patent, certain U.S. patents, U.S. patent applications, and other materials (e.g., articles) have been incorporated by reference. The text of such U.S. patents, U.S. patent applications, and other materials is, however, only incorporated by reference to the extent that no conflict exists between such text and the other statements and drawings set forth herein. In the event of such conflict, then any such conflicting text in such incorporated by reference U.S. patents, U.S. patent applications, and other materials is specifically not incorporated by reference in this patent.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1-106. (canceled)

107. A semiconductor substrate processing apparatus, comprising:
a substrate load lock chamber;
a plurality of storage bays configured for storing semiconductor substrates;
a first set of one or more multi-axis robot arms configured to transfer one or more semiconductor substrates between the substrate load lock chamber and the plurality of storage bays;
a substrate transfer chamber vacuum coupled to the substrate load lock chamber;
a plurality of process chamber modules vacuum coupled to the substrate transfer chamber; and
a second set of one or more multi-axis robot arms configured to transfer semiconductor substrates between the storage bays and the plurality of process chamber modules under sub-atmospheric conditions.

108. The apparatus of claim 107, wherein the first set of multi-axis robot arms is configured to operate independently of the second set of multi-axis robot arms.

109. The apparatus of claim 107, wherein at least one of the storage bays is configured for storing at least one of the substrates before the substrate is transferred to a process chamber module.

110. The apparatus of claim 107, wherein at least one of the storage bays is configured for storing at least one of the substrates after the substrate has been processed in a process chamber module.

111. The apparatus of claim 107, wherein at least one of the storage bays is configured for storing at least one of the substrates before the substrate is removed from the apparatus.

112. The apparatus of claim 107, wherein the plurality of storage bays are located in the substrate transfer chamber.

113. The apparatus of claim 107, wherein the plurality of storage bays are located in the substrate load lock chamber.

114. The apparatus of claim 107, wherein each storage bay is individually vacuum coupled to the substrate load lock chamber.

115. The apparatus of claim 107, wherein the first set and/or the second set of multi-axis robot arms comprise robot arms with at least 3 degrees of freedom.

116. The apparatus of claim 107, wherein the first set and/or the second set of multi-axis robot arms comprise robot arms with at least 6 degrees of freedom.

117. The apparatus of claim 107, wherein the first set and/or the second set of multi-axis robot arms are configured to move in three-dimensional paths.

118. The apparatus of claim 107, wherein the first set and/or the second set of multi-axis robot arms are configured to automatically transfer semiconductor substrates.

119. The apparatus of claim 107, further comprising one or more robotic controllers configured to control the movement of the first set and/or the second set of multi-axis robot arms.

120. The apparatus of claim 107, wherein the plurality of process chamber modules are arranged in a horizontal cluster of vertically stacked process chamber modules around the substrate transfer chamber.

121. The apparatus of claim 107, wherein the apparatus is configured to process a plurality of semiconductor substrates substantially simultaneously.

122. The apparatus of claim 107, wherein the apparatus is configured to perform a plurality of semiconductor substrate processes substantially simultaneously.

123. The apparatus of claim 107, wherein each of the process chamber modules can be independently vacuum isolated from the substrate transfer chamber.

124. The apparatus of claim 107, wherein the apparatus is configurable to process semiconductor substrates with a diameter in a range from about 100 mm to about 450 mm.

125. The apparatus of claim 107, further comprising a process control system configured to control operation of the first set and the second set of multi-axis robot arms such that the process control system controls the movement of semiconductor substrates in the apparatus.

126. A semiconductor substrate processing apparatus, comprising:
a substrate loading chamber;
a substrate load lock chamber;
a plurality of storage bays configured for storing semiconductor substrates;
a first set of one or more multi-axis robot arms configured to transfer one or more semiconductor substrates between the substrate loading chamber and the plurality of storage bays;
a substrate transfer chamber vacuum coupled to the substrate load lock chamber;
a plurality of process chamber modules vacuum coupled to the substrate transfer chamber; and
a second set of one or more multi-axis robot arms configured to transfer semiconductor substrates between the storage bays and the plurality of process chamber modules under sub-atmospheric conditions.

127. A semiconductor substrate processing apparatus, comprising:
a substrate loading chamber;
a substrate load lock chamber;
a plurality of storage bays configured for storing semiconductor substrates;
a first set of one or more multi-axis robot arms in the substrate load lock chamber configured to transfer one or more semiconductor substrates between the substrate loading chamber and the plurality of storage bays;
a substrate transfer chamber vacuum coupled to the substrate load lock chamber;
a plurality of process chamber modules vacuum coupled to the substrate transfer chamber; and
a second set of one or more multi-axis robot arms in the substrate transfer chamber configured to transfer semiconductor substrates between the storage bays and the plurality of process chamber modules under sub-atmospheric conditions.

128-255. (canceled)
